(19) United States
(12) Patent Application Publication
(10) Pub. No.: US 2010/0220157 A1
(43) Pub. Date: Sep. 2, 2010

(54) INK-JET HEAD AND METHOD FOR MANUFACTURING THE SAME

(75) Inventors: Boum-Seock Kim, Suwon-si (KR); Jae-Woo Joung, Suwon-si (KR); Ju-Hwan Yang, Suwon-si (KR); Young-Seuck Yoo, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/620,233

(22) Filed: Nov. 17, 2009

(30) Foreign Application Priority Data
Mar. 2, 2009 (KR) 10-2009-0017495

(51) Int. Cl. B41J 2/045; H01L 41/22; B23P 17/00

(52) U.S. Cl. 347/68; 29/25.35; 29/890.1

(57) ABSTRACT

An ink-jet head and a method for manufacturing the ink-jet head are disclosed. A method for manufacturing an ink-jet head, which has a membrane formed on one side of a chamber housing ink, can include: forming a piezoelectric component over a glass substrate, attaching the piezoelectric component onto the membrane, irradiating a laser to an interface between the piezoelectric component and the glass substrate such that the piezoelectric component and the glass substrate are separated, and separating the piezoelectric component and the glass substrate. According to certain embodiments of the invention as set forth above, the actuator of the ink-jet head can be implemented in the form of a thin film, and as such, the electrical properties of the ink-jet head can be improved.

### CROSS-REFERENCE TO RELATED APPLICATIONS

This application claims the benefit of Korean Patent Application No. 10-2009-0017495, filed with the Korean Intellectual Property Office on Mar. 2, 2009, the disclosure of which is incorporated herein by reference in its entirety.

### BACKGROUND

1. Technical Field

The present invention relates to an ink-jet head and to a method for manufacturing the ink-jet head.

2. Description of the Related Art

An ink-jet printer is a device that performs a printing operation by converting electrical signals into physical forces to eject ink droplets through nozzles. An ink-jet head can be manufactured by processing various parts, such as the chamber, restrictor, nozzle, etc., in a number of layers and then attaching the layers together.

In recent times, application of the ink-jet head has expanded beyond the graphic printing industry to manufacturing electronic parts, such as printed circuit boards, LCD panels, etc.

Printing applications for electronic parts may require ejecting ink with higher accuracy and precision compared to graphic printing applications, and as such, various functions that have not been required before may now be required. Basic requirements may include reductions in droplet sizes and speed deviations, while other requirements for increasing productivity may involve higher densities of nozzles and higher frequencies in printing.

Operation of a conventional ink-jet head may utilize the piezoelectric qualities of a thick-film piezoelectric component. A thick-film piezoelectric component can be easy to manufacture and may provide superior piezoelectric qualities. However, decreasing the thickness of the piezoelectric component to lower the operating voltage may result in reduced piezoelectric qualities.

### SUMMARY

An aspect of the invention provides an ink-jet head and a method for manufacturing the ink-jet head, which includes an actuator in the form of a thin film.

Another aspect of the invention provides a method for manufacturing an ink-jet head, which has a membrane formed on one side of a chamber housing ink. The method can include: forming a piezoelectric component over a glass substrate, attaching the piezoelectric component onto the membrane, irradiating a laser to an interface between the piezoelectric component and the glass substrate such that the piezoelectric component and the glass substrate are separated, and separating the piezoelectric component and the glass substrate.

Here, forming the piezoelectric component may be performed by depositing a piezoelectric material on the glass substrate. In this case, the glass substrate may contain magnesium oxide (MgO) or aluminum oxide (Al₂O₃) monocrystals.

The laser used here can be an excimer laser.

The method for manufacturing an ink-jet head according to an aspect of the invention can further include, after the operation of separating the piezoelectric component and the glass substrate: removing an amorphous layer created on the piezoelectric component, for example, by ion milling over the piezoelectric component.

In certain embodiments, the method can include forming the membrane by depositing a conductive polymer over the chamber, before the forming of the piezoelectric component, and can also include forming a conductive layer over the piezoelectric component, after the separating of the glass substrate.

Yet another aspect of the invention provides an ink jet head that includes: a chamber for housing ink, a nozzle formed on one side of the chamber, a membrane containing polymers and formed on the other side of the chamber, and an actuator formed over the membrane.

Here, the membrane may contain conductive polymers. The actuator can include a piezoelectric component formed over the membrane, and an upper electrode formed over the piezoelectric component.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a side cross-sectional view illustrating a portion of an ink-jet head according to an embodiment of the invention.

FIG. 2 is a front cross-sectional view illustrating a portion of an ink-jet head according to an embodiment of the invention.

FIG. 3 is a flowchart illustrating a method for manufacturing an ink-jet head according to an embodiment of the invention.

FIG. 4, FIG. 5, FIG. 6, and FIG. 7 are cross-sectional views collectively illustrating a method for manufacturing an ink-jet head according to an embodiment of the invention.

### DETAILED DESCRIPTION

An ink-jet head and a method for manufacturing the ink-jet head according to certain embodiments of the invention will be described below in more detail with reference to the accompanying drawings. Those components that are the same or are in correspondence are rendered the same reference numeral regardless of the figure number, and redundant descriptions are omitted.

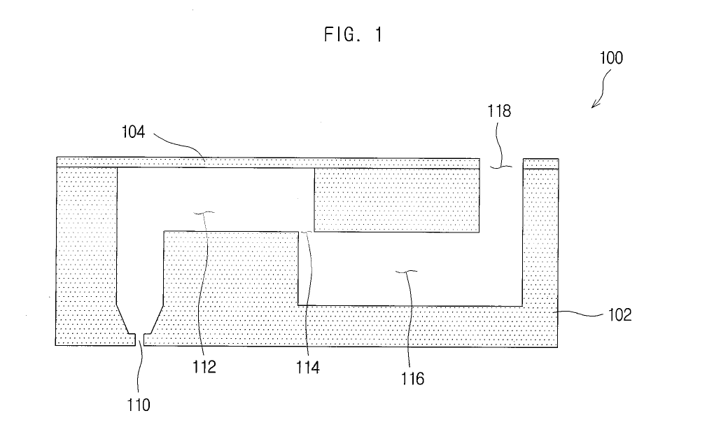

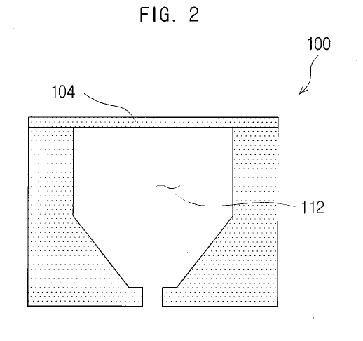

FIG. 1 is a side cross-sectional view illustrating a portion of an ink-jet head 100 according to an embodiment of the invention, and FIG. 2 is a front cross-sectional view illustrating a portion of an ink-jet head 100 according to an embodiment of the invention. As in the example shown in FIGS. 1 and 2, an ink-jet head 100 can include a reservoir 116, a restrictor 114, a chamber 112, a nozzle 110, and a membrane 104.

The reservoir 116 can be the space formed within the ink-jet head 100 in which the ink supplied through an inlet 118 from outside the ink-jet head 100 can be stored. One side of the reservoir 116 may be connected with the inlet 118, while the other side may be connected with the chamber 112.

The chamber 112 can be the space formed within the ink-jet head 100 to hold the ink. The nozzle 110 can be formed on one side of the chamber 112. The nozzle 110 can provide a passage through which the ink held in the chamber 112 may be ejected to the exterior of the ink-jet head 100. A restrictor 114 can be formed between the chamber 112 and the reservoir 116, the restrictor 114 providing a passage through which the ink held in the reservoir 116 may move to the chamber 112.

The membrane 104 can be formed on the other side of the chamber 112, across from the nozzle 110. The membrane 104 can serve as a vibration plate, transferring the vibrations generated by an actuator (not shown) to the chamber 112. The vibrations transferred by way of the membrane 104 may force the ink held in the chamber 112 to be ejected through the nozzle 110 to the exterior of the ink-jet head 100.

To facilitate the transfer of vibrations, the membrane 104 can be made from a flexible material, containing polymers, for example. If the membrane 104 contains conductive polymers, for example, and thus exhibits conductivity, the membrane 104 can also be used as a lower electrode that provides an electrical connection to the actuator.

The main body 102 of the ink-jet head 100 can be formed by stacking a number of silicon wafers together, in which elements of the ink jet head 100, such as the nozzle 110, chamber 112, reservoir 116, inlet 118, etc., are formed. Here, it is possible to form the membrane 104 by depositing conductive polymers over one side of the silicon wafer in which the chamber 112 and inlet 118 are to be formed.

Afterwards, the inlet 118 and the chamber 112 may be formed by selectively etching either side of the silicon wafer, and this silicon wafer may be attached to other silicon wafers in which the nozzle 110, reservoir 116, etc., are formed, to implement a portion of an ink-jet head 100.

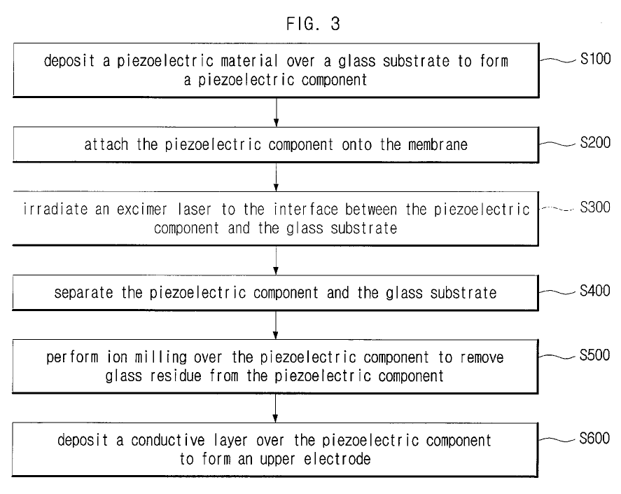

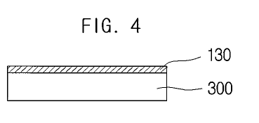

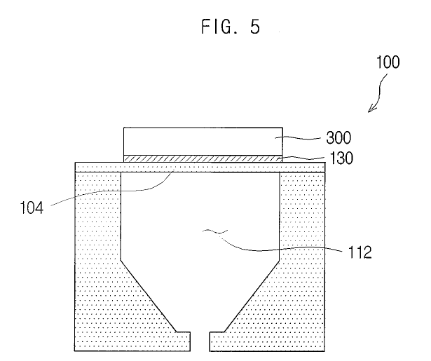

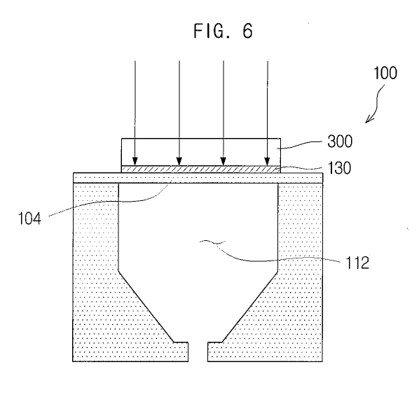

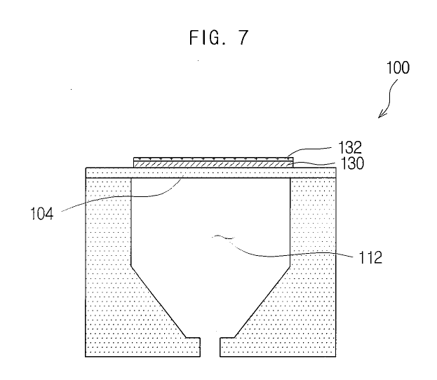

FIG. 3 is a flowchart illustrating a method for manufacturing an ink-jet head 100 according to an embodiment of the invention, while FIGS. 4 to 7 are cross-sectional views collectively illustrating a method for manufacturing an ink-jet head 100 according to an embodiment of the invention. As illustrated in FIGS. 3 and 4, a piezoelectric component 130 may first be formed by depositing a piezoelectric material over a glass substrate 300 (Operation S100).

The glass substrate 300 can be made from a material that allows easy depositing of the piezoelectric material, including, for example, magnesium oxide (MgO) or aluminum oxide (Al₂O₃) monocrystals.

By depositing the piezoelectric component 130 onto a glass substrate 300 that allows easy deposition, a piezoelectric component 130 can be obtained in the form of a thin film, without sacrificing the electrical properties of the piezoelectric component 130.

Next, as illustrated in FIG. 5, the piezoelectric component 130 may be attached to the membrane 104 (Operation S200). This may be achieved by arranging the glass substrate 300, to one side of which the piezoelectric component 130 has been deposited, over the membrane 104 and then applying heat between the membrane 104 containing conductive polymers and the piezoelectric component 130 so that the membrane 104 and the piezoelectric component 130 are attached.

The heating temperature can be selected such that an adhesive force is obtained between the membrane 104 and the piezoelectric component 130. In certain examples, this temperature can be about 100 degrees Celsius.

Of course, it is also conceivable to place an adhesive between the piezoelectric component 130 and the membrane 104.

Next, as illustrated in FIG. 6, an excimer laser may be irradiated on an interface between the piezoelectric component 130 and the glass substrate 300 (Operation S300). The excimer laser can be irradiated onto the interface between one side of the glass substrate 300 and the piezoelectric component 130, as the laser passes through the other side of the glass substrate 300.

The wavelength of the excimer laser can be, for example, 248 nm. Of course, it is apparent that lasers of different types and different wavelengths that are capable of raising the temperature locally at the interface of the piezoelectric component 130 and the glass substrate 300 may also be used.

When the excimer laser is irradiated, a local temperature increase may be effected at the interface of the glass substrate 300 and the piezoelectric component 130, resulting in a reduction in adhesion between the glass substrate 300 and piezoelectric component 130, such that the glass substrate 300 may be separated from the piezoelectric component 130.

Next, the piezoelectric component 130 and the glass substrate 300 may be separated (Operation S400). Since the adhesion between the glass substrate 300 and the piezoelectric component 130 was changed in the previous operation to allow separation, the glass substrate 300 on the ink-jet head 100 may readily be removed.

In this way, a thin-film piezoelectric component 130 can be coupled onto a membrane 104 containing conductive polymers. By forming the piezoelectric component 130, which may form the actuator, as a thin film, the operating voltage of the ink-jet head 100 can be reduced, and the electrical properties of the ink-jet head 100 can be improved.

Also, by using a more flexible material of conductive polymers for the membrane 104, the membrane 104 can be made to provide the displacement necessary for the ink-jet head 100 to operate, even when a thin-film piezoelectric component 130 is used for the actuator.

Next, an ion milling procedure can be performed over the piezoelectric component 130 to remove an amorphous layer created on the piezoelectric component 130 (Operation S500). During the procedure of irradiating an excimer laser on the interface to separate the piezoelectric component 130 and glass substrate 300, an undesired amorphous layer may be created.

The amorphous layer may degrade the electrical connection between the piezoelectric component 130 and the upper electrode 132, and thus degrade the operating characteristics of the piezoelectric component 130. Therefore, an operation of ion milling over the piezoelectric component 130 can prevent losses in performance of the ink-jet head 100 that may otherwise be effected by the amorphous layer.

Next, as illustrated in FIG. 7, a conductive layer may be deposited over the piezoelectric component 130 to form an upper electrode 132 (Operation S600). In certain examples, the conductive layer can be made from platinum (Pt). By depositing the upper electrode 132, an electrical connection to the piezoelectric component 130 can be obtained, by way of the membrane 104 containing conductive polymers and the upper electrode 132. Thus, an actuator can be implemented, including the piezoelectric component 130, upper electrode 132, and membrane 104 containing conductive polymers.

While this embodiment has been described using an example in which a lower electrode is omitted due to the use of a membrane 104 including conductive polymers, it is apparent that a separate lower electrode may be formed on the membrane 104, if the membrane 104 does not provide an electrical connection.

According to certain embodiments of the invention as set forth above, the actuator of the ink-jet head can be implemented in the form of a thin film, and as such, the electrical properties of the ink-jet head can be improved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing an ink-jet head having a membrane formed on one side of a chamber housing ink, the method comprising:
forming a piezoelectric component over a glass substrate;
attaching the piezoelectric component onto the membrane;
irradiating a laser to an interface between the piezoelectric component and the glass substrate such that the piezoelectric component and the glass substrate are separated; and
separating the piezoelectric component and the glass substrate.

2. The method of claim 1, wherein the forming of the piezoelectric component is performed by depositing a piezoelectric material on the glass substrate.

3. The method of claim 2, wherein the glass substrate contains magnesium oxide (MgO) or aluminum oxide (Al₂O₃) monocrystals.

4. The method of claim 1, wherein the laser is an excimer laser.

5. The method of claim 1, further comprising, after the separating of the piezoelectric component and the glass substrate, removing an amorphous layer created on the piezoelectric component.

6. The method of claim 5, wherein the removing of the amorphous layer is performed by ion milling over the piezoelectric component.

7. The method of claim 1, further comprising, before the forming of the piezoelectric component, forming the membrane by depositing a conductive polymer over the chamber.

8. The method of claim 7, further comprising, after the separating of the glass substrate, forming a conductive layer over the piezoelectric component.

9. An ink-jet head comprising:
a chamber for housing ink;
a nozzle formed on one side of the chamber;
a membrane formed on the other side of the chamber, the membrane containing polymers; and
an actuator formed over the membrane.

10. The ink-jet head of claim 9, wherein the membrane contains conductive polymers.

11. The ink jet head of claim 10, wherein the actuator comprises:
a piezoelectric component formed over the membrane; and
an upper electrode formed over the piezoelectric component.
